(19) United States
(12) Patent Application Publication
(10) Pub. No.: US 2024/0234355 A1
(43) Pub. Date: Jul. 11, 2024

(54) MODULE

(71) Applicant: Murata Manufacturing Co., Ltd., Kyoto-fu (JP)

(72) Inventors: Yoshihito OTSUBO, Nagaokakyo-shi (JP); Morio TAKEUCHI, Nagaokakyo-shi (JP)

(21) Appl. No.: 18/614,965

(22) Filed: Mar. 25, 2024

Related U.S. Application Data
(63) Continuation of application No. PCT/JP2022/031200, filed on Aug. 18, 2022.

(30) Foreign Application Priority Data
Sep. 28, 2021 (JP) 2021-158137

(51) Int. Cl. H01L 23/00; H01L 23/31; H01L 23/60; H01L 23/66; H01L 25/065

(52) U.S. Cl. CPC H01L 24/08; H01L 23/3121; H01L 23/60; H01L 23/66; H01L 24/48; H01L 25/0655; H01L 2223/6611; H01L 2224/08225; H01L 2224/48229; H01L 2924/1815

(57) ABSTRACT

A module includes a die pad arranged to locate a lower end thereof on a reference plane, a signal terminal arranged to locate a lower end thereof on the reference plane, an electronic component fixed as being superimposed above the die pad, and a sealing resin arranged to seal the die pad, the signal terminal, and the electronic component from above. The electronic component is provided with a component first surface facing a side of the die pad and a component second surface facing a side opposite to the die pad. The component second surface and the signal terminal are electrically connected to each other through a first wire. The die pad includes a die pad main body on which the electronic component is carried and a surrounding portion extending from the die pad main body along the reference plane to surround the signal terminal apart from the signal terminal.

### CROSS REFERENCE TO RELATED APPLICATION

This is a continuation of International Application No. PCT/JP2022/031200 filed on Aug. 18, 2022, which claims priority from Japanese Patent Application No. 2021-158137 filed on Sep. 28, 2021. The contents of these applications are incorporated herein by reference in their entireties.

### BACKGROUND OF THE DISCLOSURE

### Field of the Disclosure

The present disclosure relates to a module.

### Description of the Related Art

Japanese Patent No. 4535801 (PTL 1) describes a configuration in which a radio-frequency semiconductor element is mounted on a surface of an insulating substrate with a die attach being interposed and the radio-frequency semiconductor element and an electrode arranged on the surface of the insulating substrate are connected to each other through a wire. In the inside of the insulating substrate, a thermal via conductor is arranged to pass through the insulating substrate to be connected to the die attach. Heat generated in the radio-frequency semiconductor element is emitted to an opposite surface of the insulating substrate through the die attach and the thermal via conductor.

Japanese Patent No. 6438183 (PTL 2) also describes a similar configuration.
PTL 1: Japanese Patent No. 4535801
PTL 2: Japanese Patent No. 6438183

### BRIEF SUMMARY OF THE DISCLOSURE

Though heat generated from an electronic component may efficiently be dissipated in the configurations described in PTLs 1 and 2, shielding against electromagnetic waves emitted from the electronic component or electromagnetic waves incoming to the electronic component is not considered.

A possible benefit of the present disclosure is to provide a module that can enhance performance to shield an electronic component.

In order to achieve the possible benefit, a module based on the present disclosure includes a die pad arranged such that a lower end of the die pad is located on a reference plane, a signal terminal arranged such that a lower end of the signal terminal is located on the reference plane, an electronic component fixed as being superimposed above the die pad, and a sealing resin arranged to seal the die pad, the signal terminal, and the electronic component from above. The electronic component is provided with a component first surface that faces a side of the die pad and a component second surface that faces a side opposite to the die pad. The component second surface and the signal terminal are electrically connected to each other through a first wire arranged to pass through the inside of the sealing resin. The die pad includes a die pad main body on which the electronic component is carried and a surrounding portion that extends from the die pad main body along the reference plane to surround the signal terminal at a distance from the signal terminal.

According to the present disclosure, the die pad includes the surrounding portion that extends along the reference plane and the surrounding portion surrounds the signal terminal at a distance from the signal terminal. Therefore, performance to shield the electronic component in the module is enhanced.

### BRIEF DESCRIPTION OF THE SEVERAL VIEWS OF THE DRAWINGS

FIG. 1 is a perspective view of a module in a first embodiment based on the present disclosure.

FIG. 2 is a schematic plan view of the module in the first embodiment based on the present disclosure.

FIG. 3 is a cross-sectional view along the line III-III in FIG. 2.

FIG. 4 is a schematic plan view of a state in which a wire and an electronic component have further been removed from FIG. 2.

FIG. 5 is a schematic plan view of a module in a second embodiment based on the present disclosure.

FIG. 6 is a cross-sectional view along the line VI-VI in FIG. 5.

FIG. 7 is a schematic plan view of a state in which the wire and the electronic component have further been removed from FIG. 5.

FIG. 8 is a schematic plan view of a module in a third embodiment based on the present disclosure.

FIG. 9 is a cross-sectional view of the module in the third embodiment based on the present disclosure.

FIG. 10 is a schematic plan view of a module in a fourth embodiment based on the present disclosure.

FIG. 11 is a cross-sectional view along the line XI-XI in FIG. 10.

FIG. 12 is a schematic plan view of a state in which the wire and the electronic component have further been removed from FIG. 10.

FIG. 13 is a schematic plan view of a modification of the module in the fourth embodiment based on the present disclosure.

FIG. 14 is a schematic plan view of a module in a fifth embodiment based on the present disclosure.

FIG. 15 is a cross-sectional view along the line XV-XV in FIG. 14.

FIG. 16 is a schematic plan view of a module in a sixth embodiment based on the present disclosure.

FIG. 17 is a cross-sectional view along the line XVII-XVII in FIG. 16.

FIG. 18 is a schematic plan view of a module in a seventh embodiment based on the present disclosure.

FIG. 19 is a cross-sectional view of the module in the seventh embodiment based on the present disclosure.

FIG. 20 is a schematic plan view of a module in an eighth embodiment based on the present disclosure.

FIG. 21 is a cross-sectional view of the module in the eighth embodiment based on the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

### First Embodiment

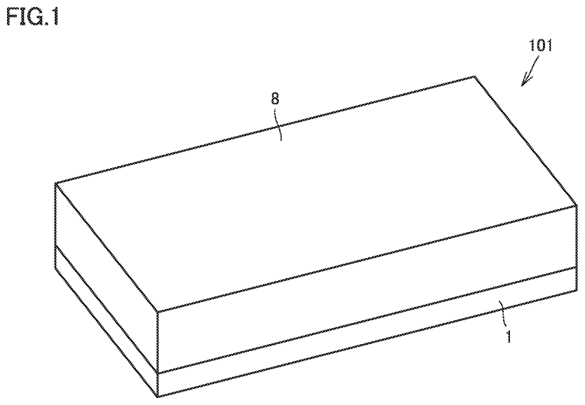

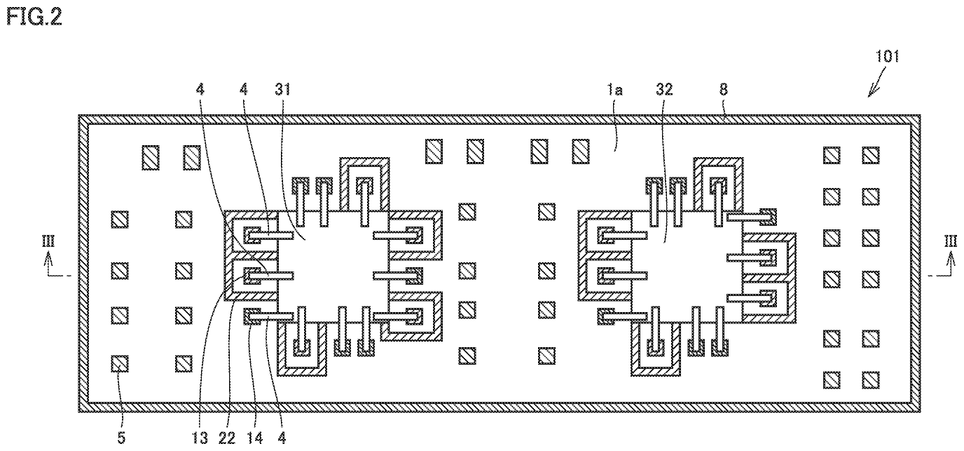

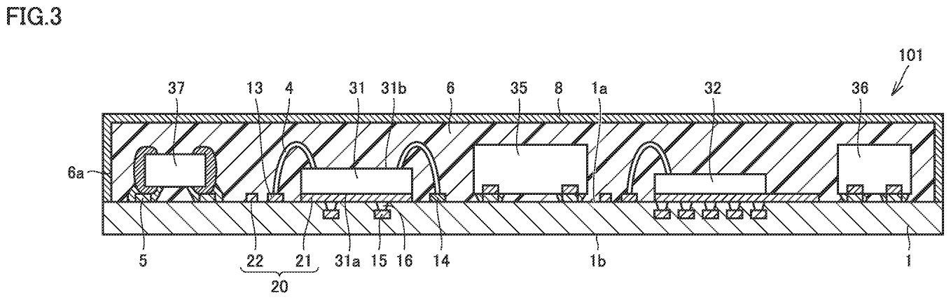

A module in a first embodiment based on the present disclosure will be described with reference to FIGS. 1 to 4. FIG. 1 shows a perspective view of a module 101 in the present embodiment. FIG. 2 shows a two-dimensional plan view when a shield film 8 that covers an upper surface of module 101 is removed and a sealing resin and some mounted components are further removed. FIG. 3 shows cross-sectional view along the line III-III in FIG. 2. FIG. 3 shows also shield film 8 that covers the upper surface, a sealing resin 6, various mounted components, and the like. Module 101 includes a substrate 1. Substrate 1 is provided with a substrate first surface 1a and a substrate second surface 1b. Electronic components 31, 32, 35, 36, and 37 are mounted on substrate first surface 1a. Each electronic component mounted on substrate first surface 1a is sealed with sealing resin 6. Sealing resin 6 has an upper surface and a side surface covered with shield film 8. Shield film 8 is grounded through some route. In module 101, substrate first surface 1a is defined as a “reference plane.”

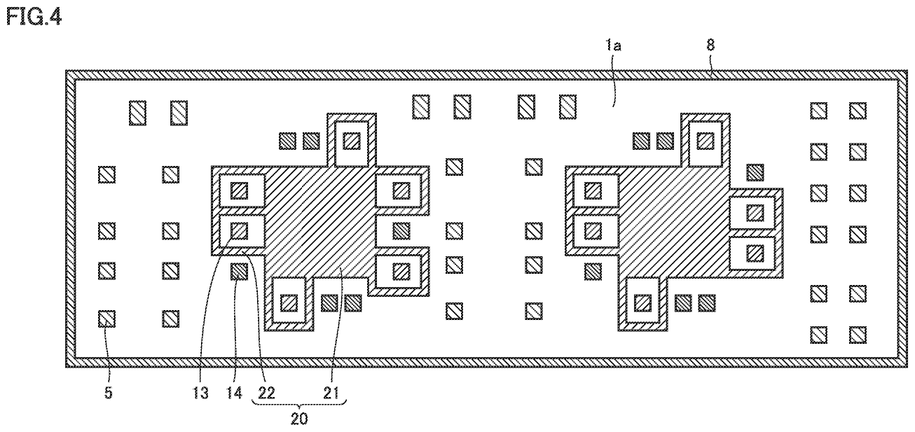

FIG. 4 shows a state in which a wire 4 and electronic components 31 and 32 have further been removed from FIG. 2. Module 101 in the present embodiment includes a die pad 20 arranged such that a lower end thereof is located on the reference plane, a signal terminal 13 arranged such that a lower end thereof is located on the reference plane, electronic component 31 fixed as being superimposed above die pad 20, and sealing resin 6 arranged to seal die pad 20, signal terminal 13, and electronic component 31 from above. Electronic component 31 is provided with a component first surface 31a that faces a side of die pad 20 and a component second surface 31b that faces a side opposite to die pad 20. Component second surface 31b and signal terminal 13 are electrically connected to each other through a first wire 4 arranged to pass through the inside of sealing resin 6. Die pad 20 includes a die pad main body 21 on which electronic component 31 is carried and a surrounding portion 22 that extends from die pad main body 21 along the reference plane to surround signal terminal 13 at a distance from signal terminal 13. Die pad 20 is finally grounded through a line provided in substrate 1.

Die pad 20 is formed of a conductor. Die pad 20 is formed, for example, of metal. Die pad 20 may be formed by patterning a metallic film into a desired shape. Electronic component 31 or 32 is also called a “die”. Electronic component 31 may be, for example, a low noise amplifier (LNA), a power amplifier (PA), or a switch IC. This is also applicable to electronic component 32. Die attach film (DAF) may be sandwiched between die pad 20 and electronic component 31 or 32. In this case, as the DAF, a conductive DAF is preferable from the viewpoint of heat dissipation.

In the present embodiment, since die pad 20 includes surrounding portion 22 and surrounding portion 22 surrounds signal terminal 13 at a distance therefrom, performance to shield electronic component 31 in module 101 is enhanced.

In addition, since die pad 20 includes surrounding portion 22 and surrounding portion 22 extends from die pad main body 21 along the reference plane, heat radiation capability in module 101 is improved. Die pad 20 is grounded.

Though an exemplary configuration in which the upper surface and the side surface of sealing resin 6 are covered with shield film 8 is shown in the present embodiment, presence of shield film 8 is not essential. A configuration in which sealing resin 6 is not covered with shield film 8 may be applicable, which is also applicable in other embodiments.

Though the configuration in which the side surface of substrate 1 is not covered with shield film 8 is shown in the present embodiment, a configuration in which the side surface of substrate 1 is also covered with shield film 8 may be applicable, which is also applicable in other embodiments.

In an example where surrounding portion 22 which is a part of die pad 20 surrounds signal terminal 13, the surrounding portion in a form of a completely continuous line as shown in FIG. 2 may surround the signal terminal. Surrounding portion 22 in a form of a dashed line, a dotted line, or the like instead of the completely continuous line, however, may surround the signal terminal. In other words, surrounding portion 22 may be in the form of the dashed line or the dotted line. When surrounding portion 22 is in the form of the dashed line, an interval between lines may preferably be not larger than ½ of a wavelength λ of assumed electromagnetic noise. An interval between dots in an example where surrounding portion 22 is in the form of the dotted line is also similar.

As shown in the present embodiment, preferably, sealing resin 6 is provided with a sealing resin first surface 6a that faces a side different from the reference plane and sealing resin first surface 6a is covered with shield film 8. By adoption of this configuration, electromagnetic waves can be cut off by shield film 8, and hence shielding of the entire module can be enhanced. Though an example in which sealing resin first surface 6a is the side surface of sealing resin 6 as shown in FIG. 3 is shown in the present embodiment, sealing resin first surface 6a may be the side surface or the upper surface of sealing resin 6.

The following is applicable to the number of conductor vias 16 connected to a lower side of die pad 20. When importance is placed on heat radiation, a larger number of conductor vias 16 may be arranged on the lower side of the PA and a smaller number of conductor vias 16 may be arranged on the lower side of the LNA. An example in which electronic component 31 is the LNA and electronic component 32 is the PA is shown in the present embodiment by way of example. Therefore, as shown in FIG. 3, a larger number of conductor vias 16 are arranged on the lower side of electronic component 32.

When importance is placed on enhancement of shielding, on the other hand, to the contrary, a larger number of conductor vias 16 may be arranged on the lower side of the LNA that tends to be affected by electromagnet noise and a smaller number of conductor vias 16 may be arranged on the lower side of the PA.

### Second Embodiment

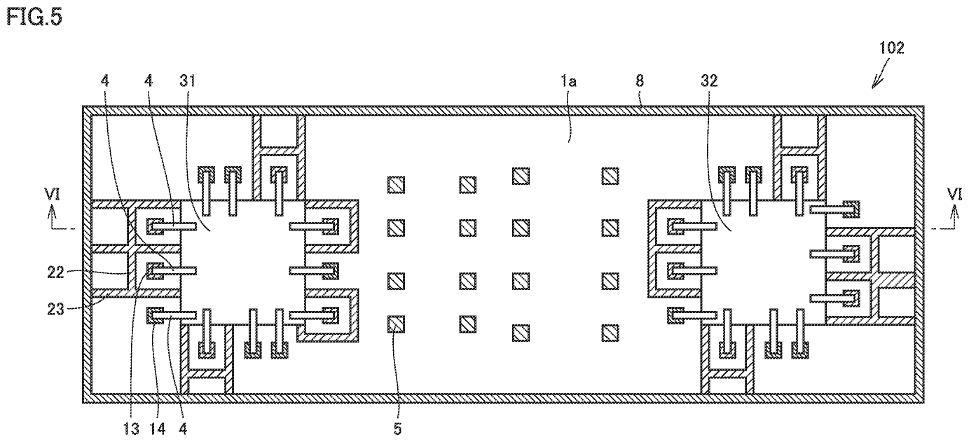

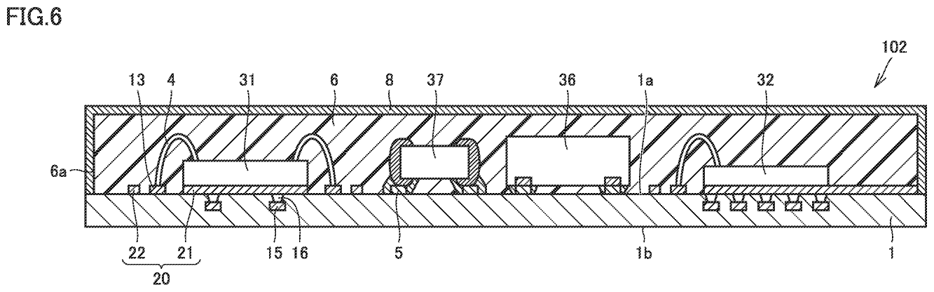

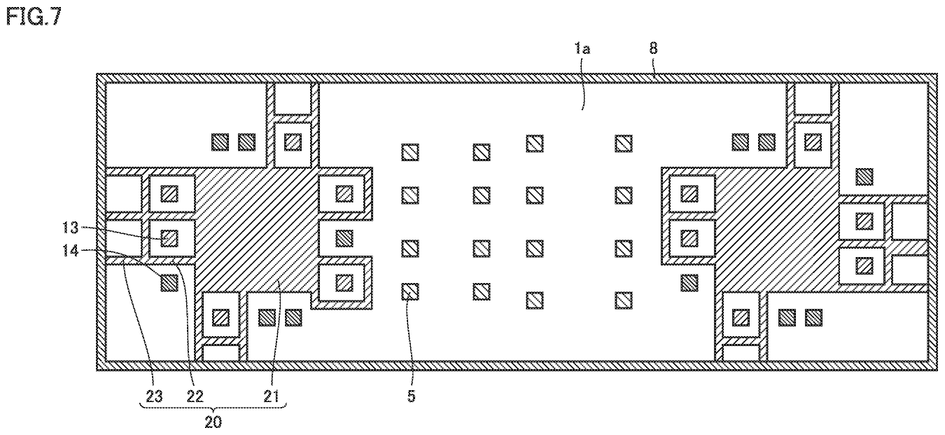

A module in a second embodiment based on the present disclosure will be described with reference to FIGS. 5 to 7. FIG. 5 shows a module 102 in the present embodiment in a plan view, in accordance with a concept the same as in FIG. 2. FIG. 6 shows a cross-sectional view along the line VI-VI in FIG. 5. FIG. 6 shows also shield film 8 that covers the upper surface, sealing resin 6, various mounted components, and the like. FIG. 7 shows a state in which wire 4 and electronic components 31 and 32 have further been removed from FIG. 5.

Module 102 in the present embodiment is common in basic configuration to module 101 described in the first embodiment. In module 102, die pad 20 includes a portion connected to shield film 8. Die pad 20 includes a shield connection portion 23 that extends from die pad main body 21 along the reference plane. Shield connection portion 23 is electrically connected to shield film 8 at a joint between sealing resin first surface 6a and the reference plane.

The present embodiment can also achieve the effects described in the first embodiment. Furthermore, since die pad 20 includes shield connection portion 23, shield film 8 can be grounded through shield connection portion 23. Thus, a pad electrode for grounding of shield film 8 does not have to separately be provided, or a line exposed at the side surface of substrate 1 for connection to shield film 8 does not have to be provided. Consequently, a degree of freedom in a design area increases.

### Third Embodiment

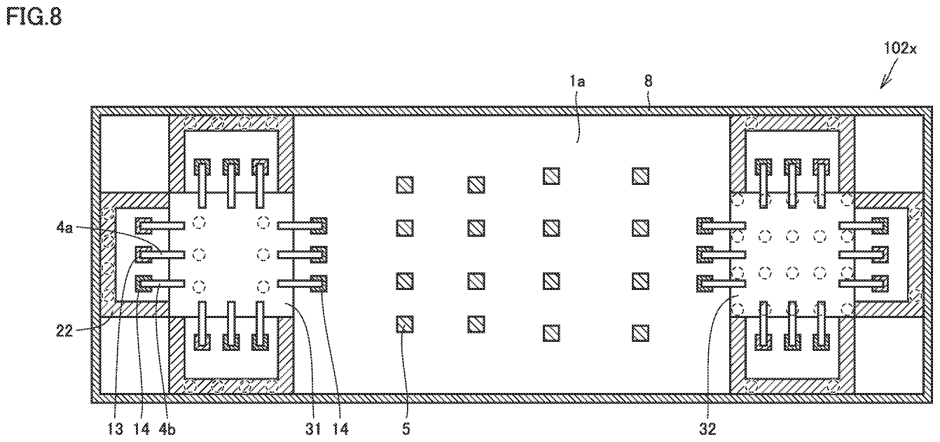

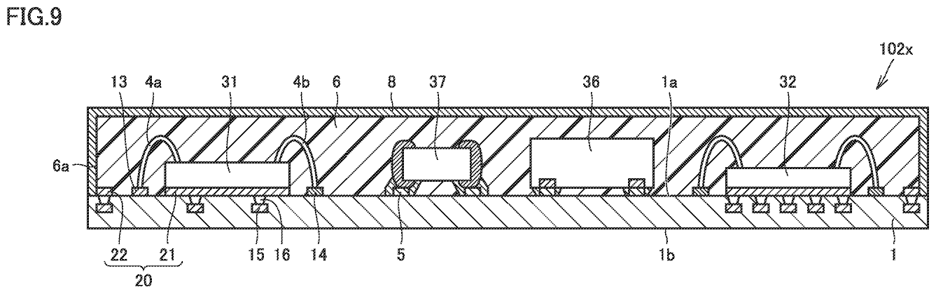

A module in a third embodiment based on the present disclosure will be described with reference to FIGS. 8 to 9. FIG. 8 shows a module 102x in the present embodiment in a plan view, in accordance with the concept the same as in FIG. 2. FIG. 9 shows a cross-sectional view of module 102x. FIG. 9 shows also shield film 8 that covers the upper surface, sealing resin 6, various mounted components, and the like. FIG. 8 shows conductor via 16 with a dashed line.

When suppression of electromagnetic interference from the outside of the module is desired more than enhancement of isolation between signal terminals 13 of electronic component 31, a configuration in which signal terminal 13 and GND terminal 14 are collectively surrounded by surrounding portion 22 as shown in the present embodiment may be applicable. While surrounding portion 22 widely surrounds signal terminal 13 and GND terminal 14, it is connected also to shield film 8. Conductor via 16 is connected not only to die pad main body 21 but also to surrounding portion 22. For example, on a left side, an upper side, and a lower side of electronic component 31 in FIG. 8, signal terminal 13 and GND terminal 14 are aligned as being mixed and surrounding portion 22 surrounds them collectively. On a right side of electronic component 31 in FIG. 8, however, only three GND terminals 14 are aligned and there is no signal terminal 13. Therefore, surrounding portion 22 is not provided on this side.

The present embodiment can also achieve the effects described in the first embodiment. Furthermore, since conductor via 16 connected to surrounding portion 22 of die pad 20 can be used for grounding of shield film 8, a path for grounding of shield film 8 can be reinforced. Thus, a pad electrode for grounding of shield film 8 does not have to separately be provided, or a line exposed at the side surface of substrate 1 for connection to shield film 8 does not have to be provided. Consequently, a degree of freedom in a design area increases.

### Fourth Embodiment

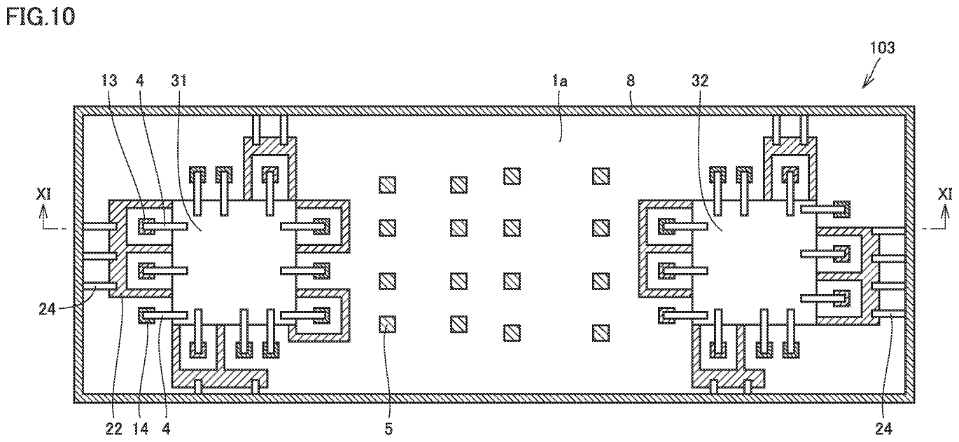

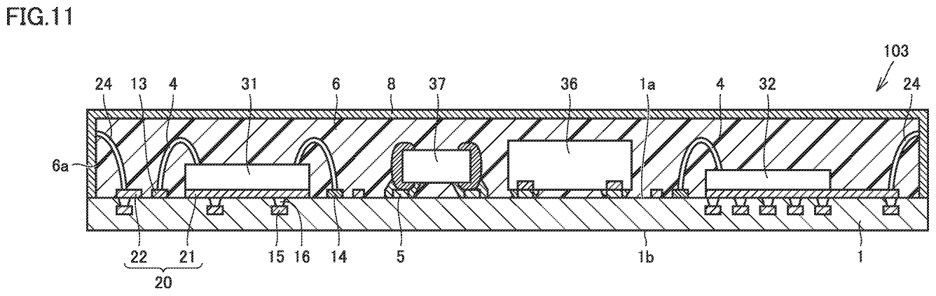

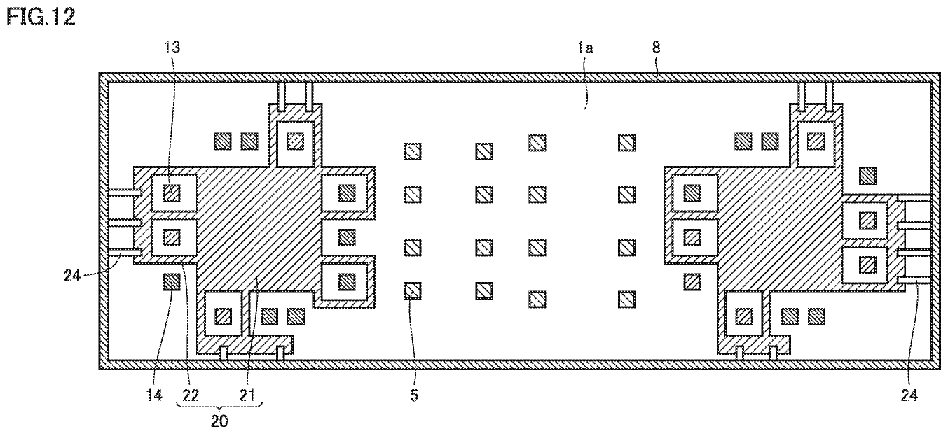

A module in a fourth embodiment based on the present disclosure will be described with reference to FIGS. 10 to 12. FIG. 10 shows a module 103 in the present embodiment in a plan view, in accordance with the concept the same as in FIG. 2. FIG. 11 shows a cross-sectional view along the line XI-XI in FIG. 10. FIG. 11 shows also shield film 8 that covers the upper surface, sealing resin 6, various mounted components, and the like. FIG. 12 shows a state in which wire 4 and electronic components 31 and 32 have further been removed from FIG. 10.

Module 103 in the present embodiment is common in basic configuration to module 102 described in the second embodiment. In the present embodiment, die pad 20 is distant from shield film 8, and instead, die pad 20 and shield film 8 are connected to each other through a second wire 24. More specifically, surrounding portion 22 which is a part of die pad 20 and shield film 8 are connected to each other through second wire 24. In module 103, second wire 24 is arranged in the inside of sealing resin 6 so as to electrically connect die pad 20 to shield film 8 at any point selected in sealing resin first surface 6a.

The present embodiment can also achieve the effects described in the first embodiment. Furthermore, since die pad 20 and shield film 8 are connected to each other through second wire 24, shielding can be enhanced. In the present embodiment, since shield film 8 and second wire 24 can be connected to each other at a high position in the side surface of module 103 when viewed from substrate first surface 1a, shielding against electromagnetic waves particularly at the high position can be enhanced.

### Modification

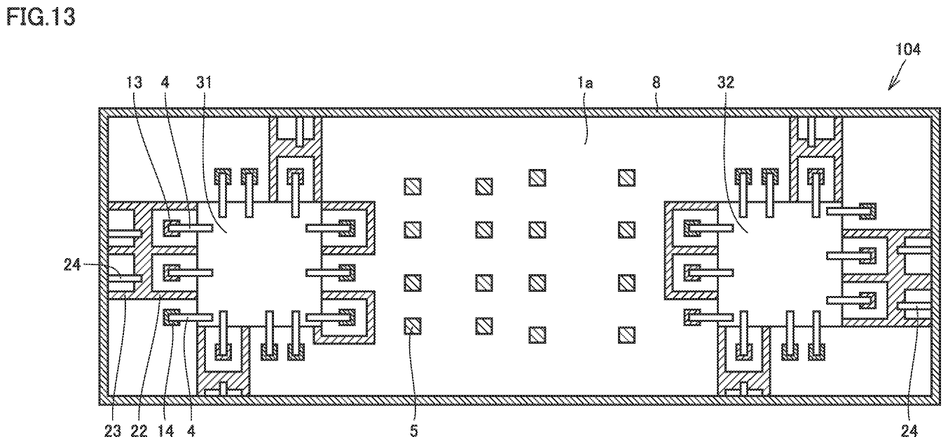

The configuration in the second embodiment and the configuration in the present embodiment can also be employed together. FIG. 13 shows as a modification of the present embodiment, an exemplary configuration in which the configurations are employed together. In a module 104 shown in FIG. 13, die pad 20 includes shield connection portion 23 as a portion directly connected to shield film 8 and die pad 20 and shield film 8 are connected to each other also through second wire 24. By adoption of this configuration, shielding can further be enhanced.

### Configuration of Module Without Substrate

Modules shown in fifth to eighth embodiments below do not include a substrate. In other words, these modules have what is called a coreless structure. In these modules, a lower surface 6c of sealing resin 6 is defined as the “reference plane.” Lower surface 6c of sealing resin 6 is exposed to the outside as it is. In these modules, the lower surface of die pad 20, a pad electrode 5, signal terminal 13, and a lower surface of GND terminal 14 are flush with lower surface 6c.

### Fifth Embodiment

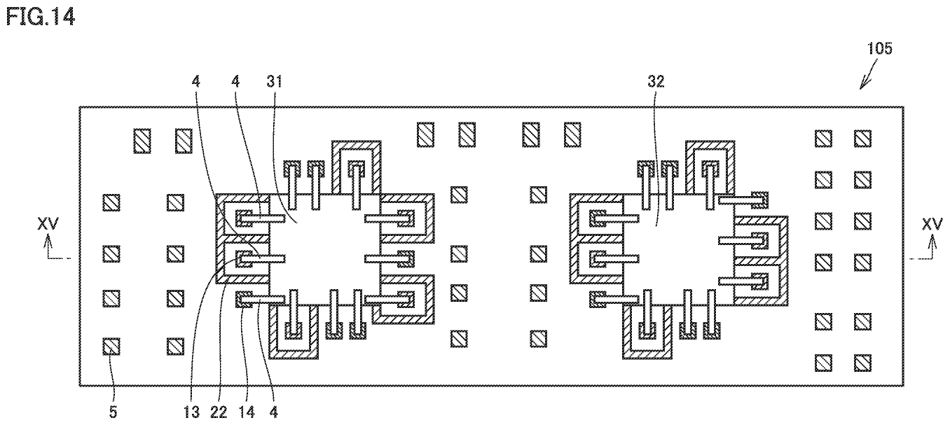

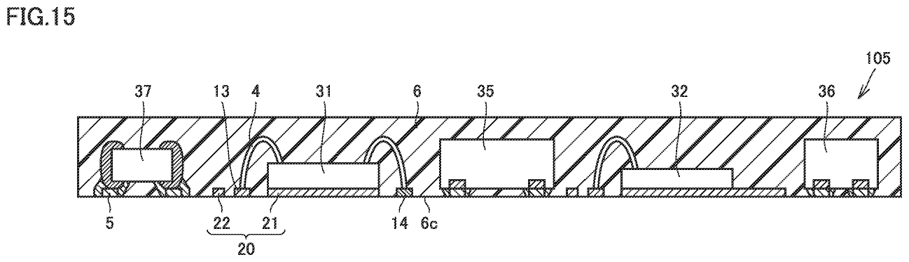

A module in a fifth embodiment based on the present disclosure will be described with reference to FIGS. 14 to 15. FIG. 14 shows a module 105 in the present embodiment in a plan view, in accordance with the concept the same as in FIG. 2. FIG. 15 shows a cross-sectional view along the line XV-XV in FIG. 14. FIG. 15 shows also sealing resin 6, various mounted components, and the like. Module 105 does not include shield film 8.

The present embodiment can also achieve the effects described in the first embodiment.

### Sixth Embodiment

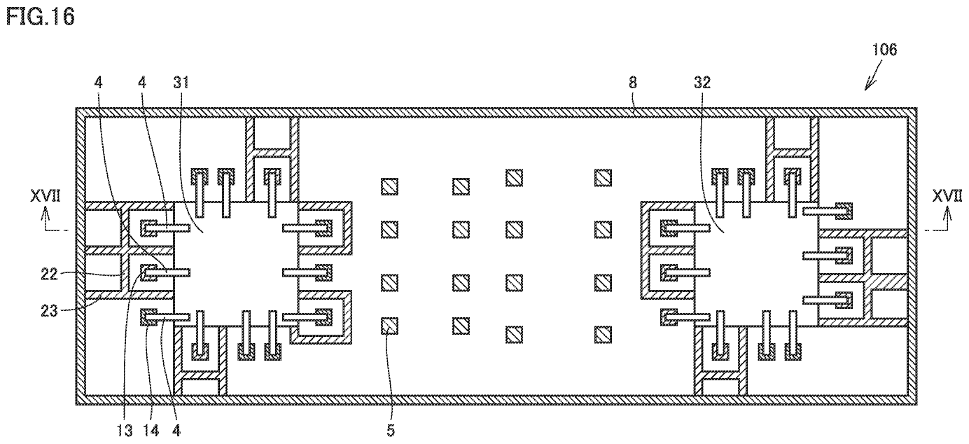

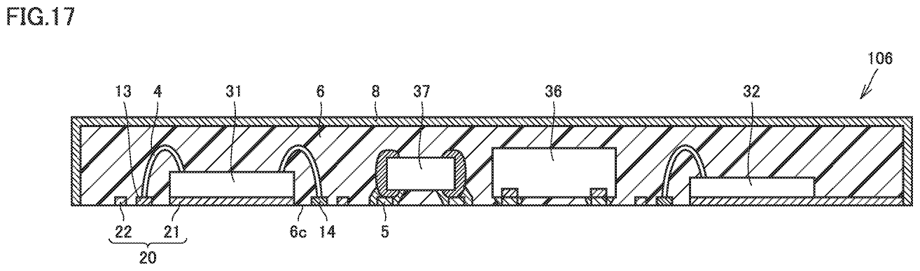

A module in a sixth embodiment based on the present disclosure will be described with reference to FIGS. 16 to 17. FIG. 16 shows a module 106 in the present embodiment in a plan view, in accordance with the concept the same as in FIG. 2. FIG. 17 shows a cross-sectional view along the line XVII-XVII in FIG. 16. FIG. 17 shows also sealing resin 6, shield film 8, various components, and the like. Module 106 includes shield film 8. Die pad is grounded.

The present embodiment can also achieve the effects described in the first embodiment.

### Seventh Embodiment

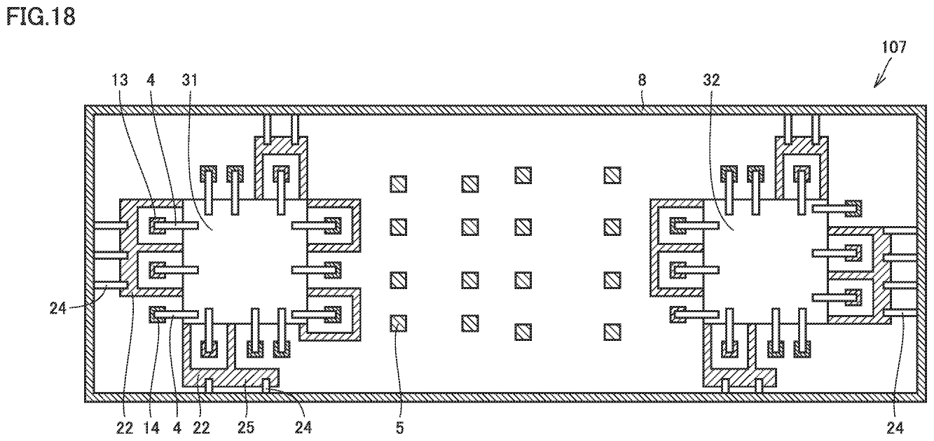

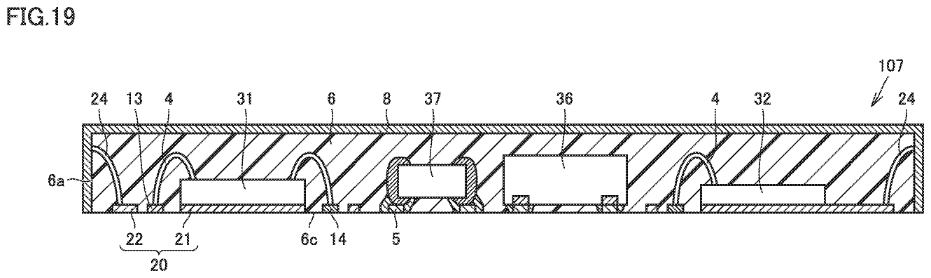

A module in a seventh embodiment based on the present disclosure will be described with reference to FIGS. 18 to 19. FIG. 18 shows a module 107 in the present embodiment in a plan view, in accordance with the concept the same as in FIG. 2. FIG. 19 shows a cross-sectional view of module 107. Module 107 in the present embodiment is similar to module 102 described in the second embodiment being modified to have the coreless structure. In module 107, as shown on the lower side of electronic component 31 in FIG. 18, a part of die pad 20 includes a projecting portion 25 that extends in parallel to the side surface at a position distant from the side surface of module 107. Projecting portion 25 and shield film 8 that covers the side surface are connected to each other through second wire 24. Die pad 20 may thus be provided with projecting portion 25 for connection of second wire 24 as appropriate.

The present embodiment can also achieve the effects described in the first embodiment.

### Eighth Embodiment

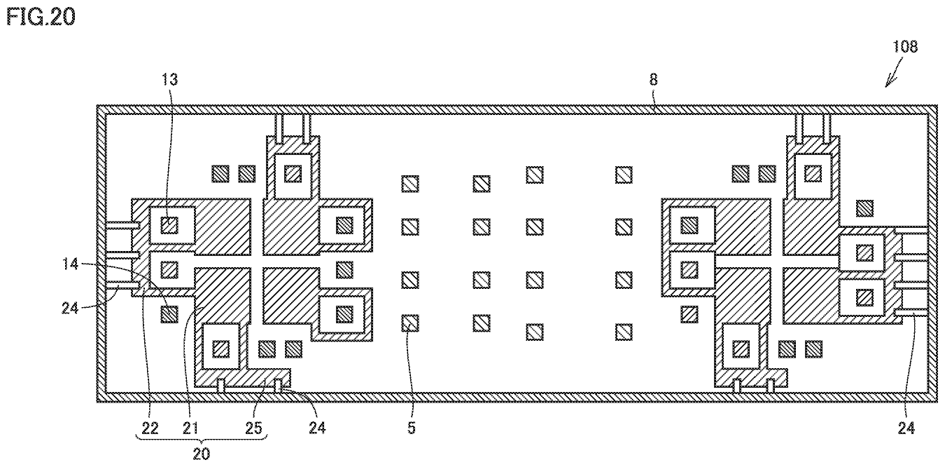

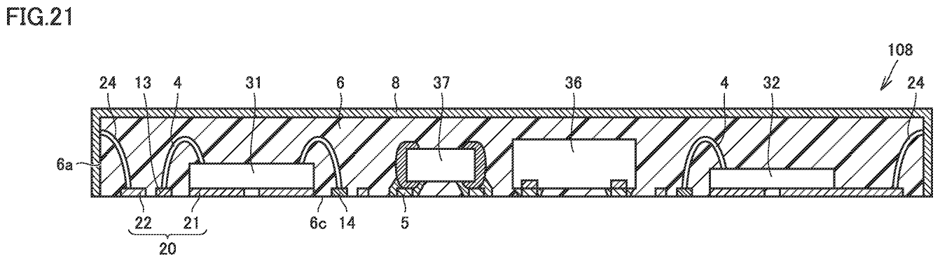

A module in an eighth embodiment based on the present disclosure will be described with reference to FIGS. 20 to 21. FIG. 20 shows a module 108 in the present embodiment in a plan view, in accordance with the concept the same as in FIG. 2. FIG. 21 shows a cross-sectional view of module 108. In module 108 in the present embodiment, die pad main body 21 which is a part of die pad 20 is divided into a plurality of sections. In an example shown here, die pad main body 21 is divided into four small sections. The small sections are aligned at a distance, with a gap being interposed.

The present embodiment can also achieve the effects described in the first embodiment. As shown in the present embodiment, die pad main body 21 has a divided structure, so that individual small sections included in die pad main body 21 have a small size.

In an example where die pad main body 21 is a large monolithic object without being divided, based on comparison between a size of pad electrode 5, signal terminal 13, GND terminal 14, and the like and a size of die pad main body 21 as a whole, the latter size is considerably larger and hence an amount of solder in mounting with the use of solder tends to be varied. In an example where die pad main body 21 is divided into the plurality of small sections as in the present embodiment, however, the size of the individual small sections rather than the size of die pad main body 21 as a whole affects the amount of attached solder. A size difference in comparison between the size of pad electrode 5, signal terminal 13, GND terminal 14, and the like and the size of the individual small sections is small. Therefore, a degree of variation in amount of solder can be less in the example where die pad main body 21 has the divided structure than in examples otherwise. Consequently, such defects as splashes and insufficient soldering due to variation in amount of solder in mounting with solder, of module 108 having the coreless structure can be suppressed.

In a module having the coreless structure, a configuration in which a metallic chip is arranged directly on an inner side of shield film 8 so as to be in contact therewith on the side surface for grounding of the shield film may be applicable. Such a configuration, however, gives rise to a problem of separation that starts from the metallic chip. As compared with such a configuration, in the configuration as in the seventh and eighth embodiments, connection to the shield film on the side surface is achieved by second wire 24, and hence there is no problem of separation.

As described so far, in the fifth to eighth embodiments, the module does not include a substrate and the lower surface of the module is defined as the reference plane. Such a configuration can also achieve the effects of the present disclosure.

As described so far, in the first to fourth embodiments, the module includes substrate 1 and the surface of substrate 1 on the side of sealing resin 6 is defined as the reference plane. Such a configuration can also achieve the effects of the present disclosure.

A plurality of embodiments of the embodiments above may be adopted as being combined as appropriate.

The embodiments disclosed herein are illustrative and non-restrictive in every respect. The scope of the present disclosure is defined by the terms of the claims and is intended to include any modifications within the scope and meaning equivalent to the terms of the claims.

1 substrate; 1a substrate first surface; 1b substrate second surface; 4 first wire; 5 pad electrode; 6 sealing resin; 6a sealing resin first surface; 6c lower surface; 8 shield film; 13 signal terminal; 14 GND terminal; 15 internal electrode; 16 conductor via; 20 die pad; 21 die pad main body; 22 surrounding portion; 23 shield connection portion; 24 second wire; 25 projecting portion (for connection of wire to shield film); 31, 32 electronic component; 31a component first surface; 31b component second surface; 35, 36, 37 component; 101, 102, 102x, 103, 104, 105, 106, 107, 108 module

1. A module comprising:
a die pad arranged such that a lower end of the die pad is located on a reference plane;
a signal terminal arranged such that a lower end of the signal terminal is located on the reference plane;
an electronic component fixed as being superimposed above the die pad; and
a sealing resin arranged to seal the die pad, the signal terminal, and the electronic component from above, wherein
the electronic component is provided with a component first surface facing a side of the die pad and a component second surface facing a side opposite to the die pad,
the component second surface and the signal terminal are electrically connected to each other through a first wire arranged to pass through inside of the sealing resin, and
the die pad includes a die pad main body on which the electronic component is carried and a surrounding portion extending from the die pad main body along the reference plane to surround the signal terminal apart from the signal terminal.

2. The module according to claim 1, wherein
the sealing resin is provided with a sealing resin first surface facing a side different from the reference plane, and
the sealing resin first surface is covered with a shield film.

3. The module according to claim 2, wherein
a second wire is arranged in the inside of the sealing resin so as to electrically connect the die pad to the shield film at any point selected in the sealing resin first surface.

4. The module according to claim 2, wherein
the die pad includes a shield connection portion extending from the die pad main body along the reference plane, and the shield connection portion is electrically connected to the shield film at a joint between the sealing resin first surface and the reference plane.

5. The module according to claim 1, wherein
the reference plane is a lower surface of the module.

6. The module according to claim 1, comprising a substrate, wherein
the reference plane is a surface of the substrate facing the sealing resin.

7. The module according to claim 3, wherein
the die pad includes a shield connection portion extending from the die pad main body along the reference plane, and the shield connection portion is electrically connected to the shield film at a joint between the sealing resin first surface and the reference plane.

8. The module according to claim 2, wherein
the reference plane is a lower surface of the module.

9. The module according to claim 3, wherein
the reference plane is a lower surface of the module.

10. The module according to claim 4, wherein
the reference plane is a lower surface of the module.

11. The module according to claim 2, comprising a substrate, wherein
the reference plane is a surface of the substrate facing the sealing resin.

12. The module according to claim 3, comprising a substrate, wherein
the reference plane is a surface of the substrate facing the sealing resin.

13. The module according to claim 4, comprising a substrate, wherein
the reference plane is a surface of the substrate facing the sealing resin.
